(19) United States
(12) Patent Application Publication
(10) Pub. No.: US 2009/0268420 A1
(43) Pub. Date: Oct. 29, 2009

(54) SHIELDING ASSEMBLY

(75) Inventor: JIANG LONG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/327,436

(22) Filed: Dec. 3, 2008

(30) Foreign Application Priority Data
Apr. 24, 2008 (CN) 200810301278.7

(51) Int. Cl. H05K 7/00

(52) U.S. Cl. 361/800

(57) ABSTRACT

A shielding assembly (100) comprises a circuit board (10), a shielding frame (20), and a ground plate (30). The circuit board (10) has a plurality of ground contracts (16). The shielding frame (20) is disposed to the circuit board (10). The ground plate (30) is mounted between the circuit board (10) and the shielding frame (20), and has a plurality of pins (36) connected with the ground contracts (16).

### BACKGROUND

1. Field of the Invention

The present invention relates to shielding assemblies, particularly to shielding assemblies used in portable electronic devices.

2. Description of related art

Electromagnetic interference (EMI) occurs between neighboring electronic components or circuits due to inductive couplings. EMI sources include inverters, diodes, transistors, amplifiers, power supplies, and other circuits of electronic devices. The effective performance of electronic devices can be interrupted, obstructed, or degraded by EMI. One popular solution developed to avoid the occurrence of EMI is to employ a metallic shield to absorb as much EMI radiation energy as possible.

Traditional shielding frames are soldered to a ground wire on a printed circuit board (PCB) of a portable electronic device. The problem with the soldered-shielding frame is that considrable board space is required, especially when using side by side solder tracks. However, as portable electronic devices continue to shrink, space on circuit boards becomes a critical consideration.

Therefore, there is room for improvement within the art.

### BRIEF DESCRIPTION OF THE DRAWINGS

Many aspects of the exemplary shielding assembly can be better understood with reference to the following drawings. These drawings are not necessarily drawn to scale, the emphasis instead being placed upon clearly illustrating the principles of the present shielding assembly. Moreover, in the drawings like reference numerals designate corresponding parts throughout the several views. Wherever possible, the same reference numbers are used throughout the drawings to refer to the same or like elements of an embodiment.

FIG. 1 illustrates, in exploded perspective view, a shielding assembly according to the exemplary invention.

FIG. 2 illustrates, in exploded perspective view, the shielding assembly of FIG. 1, showing another aspect.

FIG. 3 illustrates, in assembled perspective view, the shielding assembly of FIGS. 1-2.

FIG. 4 illustrates, in exploded perspective view, the shielding assembly of FIGS. 3, as a shielding can is detached.

FIG. 5 is a partially enlarged view of the shielding assembly shown in FIG. 4.

### DETAILED DESCRIPTION OF THE EXEMPLARY EMBODIMENTS

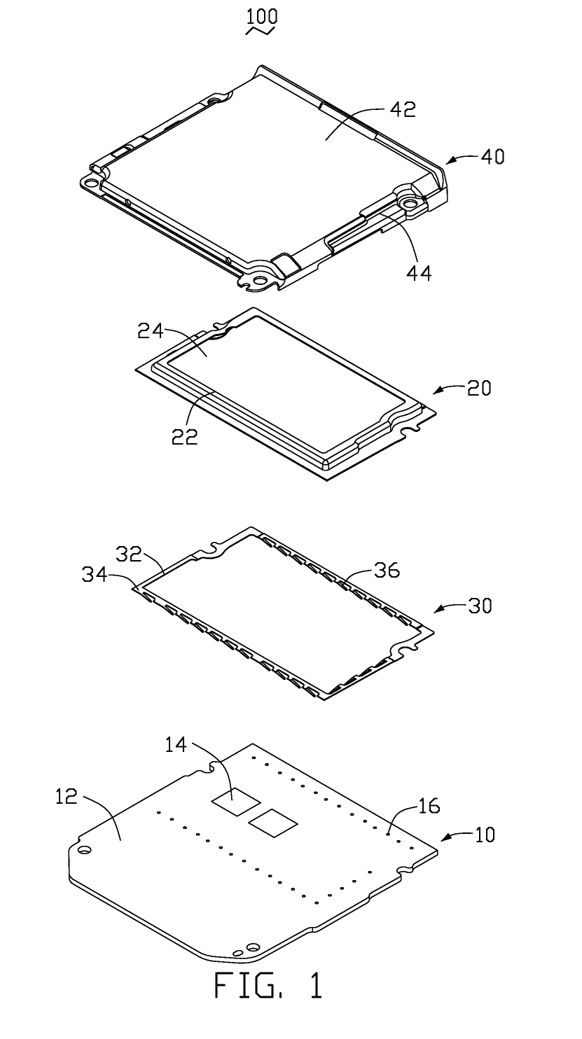

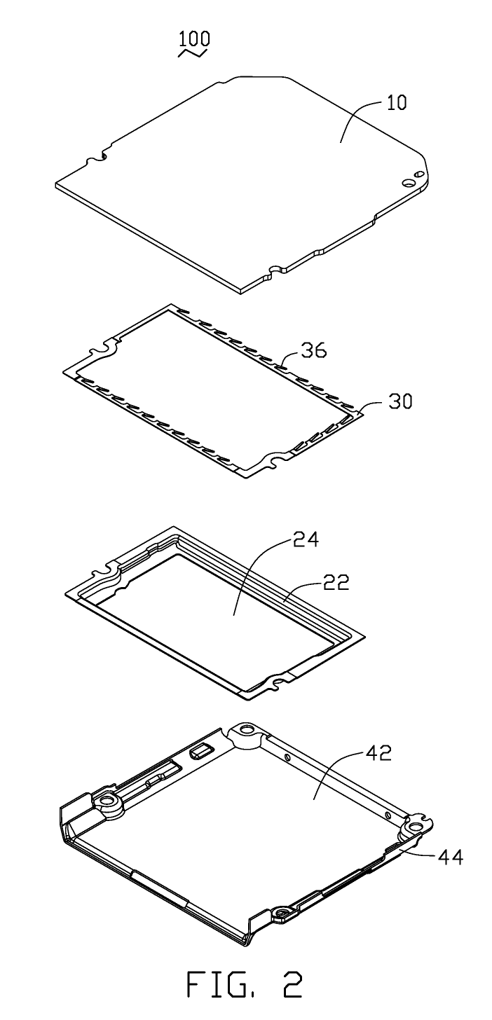

FIGS. 1 and 2 show a shielded assembly 100. The shielding assembly includes a circuit board 10, a shielding frame 20, a grounded plate 30 positioned between the circuit board 10 and the shielding frame 20, and a shielding can 40 engaged with the shielding frame 20.

The circuit board 10 is typically rectangular and includes a surface 12 facing the shielding frame 20. The surface 12 has a plurality of electronic components 14 (e.g., capacitance or resistance) disposed thereon and a plurality of ground contacts 16 configured for connecting to the ground plate 30.

The shielding frame 20 has a side wall 22 defining a chamber 24 for accommodating the electronic components 14. The shielding frame 20 is made of a metal material, such as iron or aluminum.

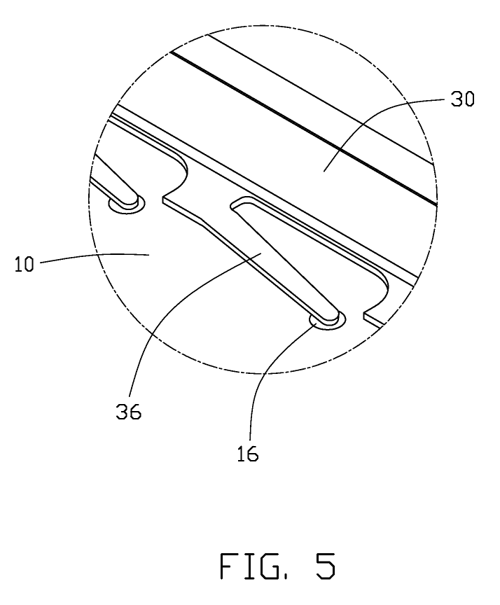

The ground plate 30 has a shape corresponding to the shape of the shielding frame 20 and includes an inner side 32 and an outer side 34. The inner side 32 has a plurality of pins 36 extending outwards in a slanted direction (FIG. 5). The pins 36 may be electrically connected with the ground contracts 16 of the circuit board 10. The ground plate 30 is made of an elastic metal, e.g., beryllium bronze or nickel alloy.

The shielding can 40 includes an upper plate 42 and a securing wall 44 protruding from a peripheral wall of the upper plate 42. The securing wall 44 is engagable with the side wall 22. The upper plate 42 has the same shape as the chamber 24, and has a size larger than the chamber 24. The shielding cap 40 is made of a metal material, e.g., iron or aluminum.

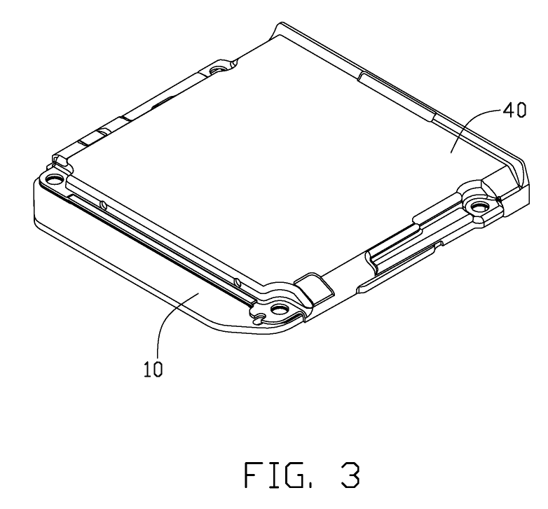

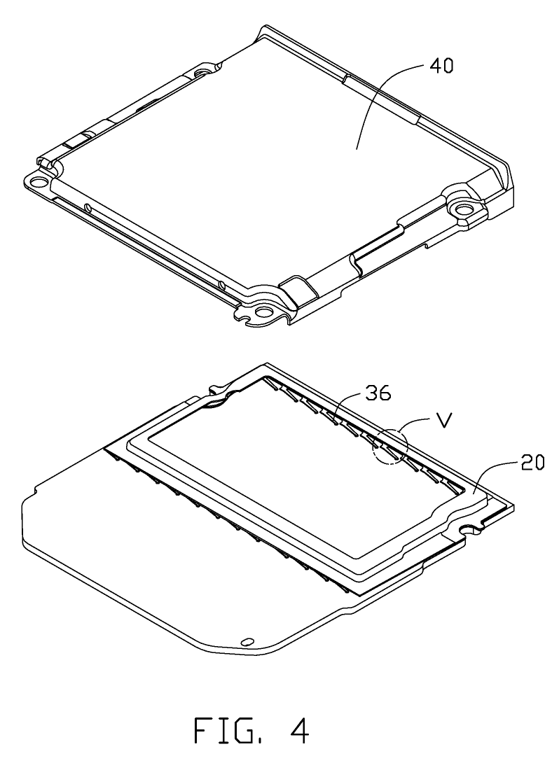

Referring to FIGS. 3-5, when assembling the shielding assembly 100, the ground plate 30 is disposed on the circuit board 10. Pins 36 tightly contact the ground contracts 16 and the pins 36 elastically deform so an elastic force keeps the pins 36 in contact with the ground contacts 16. Then, the shielding frame 20 is mounted on the ground plate 30 and secured to the circuit board 10 by fasteners, such as screws (not shown). Because the shielding frame 20 contact the ground plate 30, the electrical connection between the circuit board 10 and the shielding frame 20 occupies less space than soldered-shielding configurations. Finally, the shielding can 40 is engaged with the shielding frame 20.

It is to be further understood that even though numerous characteristics and advantages of the exemplary embodiments have been set forth in the foregoing description, together with details of structures and functions of various embodiments, the disclosure is illustrative only, and changes may be made in detail, especially in matters of shape, size, and arrangement of parts within the principles of the exemplary invention to the full extent indicated by the broad general meaning of the terms in which the appended claims are expressed.

What is claimed is:

1. A shielding assembly, comprising:
a circuit board having a plurality of ground contracts;
a shielding frame disposed to the circuit board; and
a ground plate mounted between the circuit board and the shielding frame, and having a plurality of pins connected with the ground contracts.

2. The shielding assembly as claimed in claim 1, wherein the circuit board has a plurality of electronic components disposed thereon.

3. The shielding assembly as claimed in claim 2, wherein the shielding frame includes a side wall defining a chamber for accommodating the electronic components.

4. The shielding assembly as claimed in claim 3, wherein the ground plate has a shape corresponding to the shape of the shielding frame and includes an inner side and an outer side, the pins extending from one of the inner side or the outer side.

5. The shielding assembly as claimed in claim 3, wherein the shielding assembly further includes a shielding can engaged with the shielding frame.

6. The shielding assembly as claimed in claim 5, wherein the shielding includes an upper plate and a securing wall protruding from the peripheral wall of the upper board, the securing wall engaged with the side wall.

7. The shielding assembly as claimed in claim 1, wherein the ground plate is made of an elastic metal.

8. The shielding assembly as claimed in claim 7, wherein the elastic metal is beryllium bronze or nickel alloy

9. The shielding assembly as claimed in claim 7, wherein the pins tightly contact the ground contracts and the pins are elastically deformed so the pins are electrically connected with the ground contracts by elastic force.
